(19) United States
(12) Patent Application Publication
(10) Pub. No.: US 2026/0295719 A1
(43) Pub. Date: Oct. 1, 2026

(54) SYSTEMS AND METHODS FOR LASER PROCESSING AND OPTICAL INSPECTION

(71) Applicant: Orbotech Ltd., Yavne (IL)

(72) Inventors: Boris Kling, Rehovot (IL); Mikhael Matusovsky, Rishon Lezion (IL); Asher Katz, Yavne (IL)

(21) Appl. No.: 19/090,635

(22) Filed: Mar. 26, 2025

(51) Int. Cl. B23K 26/04; B23K 26/03; B23K 26/06; B23K 26/08; B23K 26/082; B23K 26/53

(52) U.S. Cl. CPC B23K 26/043; B23K 26/032; B23K 26/0643; B23K 26/0853; B23K 26/53; B23K 26/082

(57) ABSTRACT

The system includes a camera configured to capture an image of a workpiece as a stage moves the workpiece relative to camera along a first axis, a steerable mirror configured to direct a laser beam from a laser source onto the surface of the workpiece and is movable to direct the laser beam along a second axis, and a processor configured to determine a position of a target in the image of the workpiece relative to the first axis and the second axis. The processor controls the steerable mirror to move the laser beam to align with the target along the second axis and controls the laser source to emit the laser beam to drill a hole in the workpiece at the position of the target when the laser beam is aligned with the target along the first axis by movement of the stage.

### FIELD OF THE DISCLOSURE

This disclosure relates to semiconductor fabrication and inspection and, more particularly, to laser processing of a printed circuit board.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a workpiece, such as a semiconductor wafer, using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etch, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

One type of manufacturing defect commonly found in consumer electronic parts (e.g., semiconductor wafers, integrated circuits (ICs), printed circuit boards (PCBs), flat panel displays (FPDs), etc.) is present in pads where electronic components are coupled to metal regions that define a circuit. Through-hole pads include a hole where leads of the electronic components are inserted and soldered to complete the electrical connections. These holes may be produced, for example, by drilling a hole into the pad using a laser. Where a drilled hole is misaligned with the pad, the electrical connections can fail and cause defects in the operation of the device. Thus, to improve alignment of the laser with the pad, the wafer is first inspected for alignment with fiducial features of the wafer, and then the location of each pad is calculated by coordinate transformation from the alignment fiducials as a reference. However, local distortion of the wafer can cause the actual pad position to be offset from the calculated location, which can lead to misalignment between the drilled hole and the pad. Furthermore, inspection processes performed at a separate inspection station after drilling reduce system throughput and do not reduce the number of alignment errors.

Therefore, what is needed is an improved system and method for PCB laser processing.

### BRIEF SUMMARY OF THE DISCLOSURE

An embodiment of the present disclosure provides a system. The system may comprise a stage configured to support a workpiece and move the workpiece along a first axis. The workpiece may include a first target defined on a surface of the workpiece. The system may further comprise a first camera disposed above the stage and configured to capture a first image of the workpiece as the stage moves relative to the first camera in a first direction. The first image of the workpiece may comprise the first target. The system may further comprise a laser source configured to emit a laser beam. The system may further comprise a steerable mirror configured to direct the laser beam onto the surface of the workpiece spaced apart from a field of view of the first camera in the first direction. The steerable mirror may be movable to direct the laser beam along a second axis that is orthogonal to the first axis. The system may further comprise a processor. The processor may be configured to receive the first image of the workpiece from the first camera. The processor may be further configured to determine a position of the first target in the first image of the workpiece relative to the first axis and the second axis. The processor may be further configured to send instructions to the steerable mirror to move the laser beam to align with the position of the first target along the second axis. The processor may be further configured to send instructions to the laser source to emit the laser beam to drill a first hole in the workpiece at the position of the first target when the laser beam is aligned with the position of the first target along the first axis by movement of the stage in the first direction.

In some embodiments, the first camera may be further configured to capture a second image of the workpiece as the stage moves relative to the first camera in a second direction opposite to the first direction after drilling the first hole in the workpiece at the position of the first target. The second image of the workpiece may comprise the first target and the first hole. The processor may be further configured to receive the second image of the workpiece from the first camera. The processor may be further configured to determine a position of the first hole in the second image of the workpiece relative to the first axis and the second axis to verify the position of the first hole relative to the position of the first target.

In some embodiments, the processor may be configured to verify the position of the first hole relative to the position of the first target when the first hole is centered within the first target.

In some embodiments, a plurality of targets may be defined on the surface of the workpiece. The first target may be one of the plurality of targets.

In some embodiments, the stage may be further configured to move the workpiece along the second axis to index the workpiece to align a second target of the plurality of targets with a path of the laser beam as the stage moves the workpiece along the first axis.

In some embodiments, the system may further comprise a second camera disposed above the stage, spaced apart from the laser beam in the first direction, and configured to capture a third image of the workpiece as the stage moves relative to the first camera in a second direction opposite to the first direction. The third image of the workpiece may comprise the second target. The processor may be further configured to receive the third image of the workpiece from the second camera. The processor may be further configured to determine a position of the second target in the third image of the workpiece relative to the first axis and the second axis. The processor may be further configured to send instructions to the steerable mirror to move the laser beam to align with the position of the second target along the second axis. The processor may be further configured to send instructions to the laser source to emit the laser beam to drill a second hole in the workpiece at the position of the second target when the laser beam is aligned with the position of the second target along the first axis by movement of the stage in the second direction.

In some embodiments, the second camera may be further configured to capture a fourth image of the workpiece as the stage moves relative to the second camera in the first direction after drilling the second hole in the workpiece at the position of the second target. The fourth image of the workpiece may comprise the second target and the second hole. The processor may be further configured to receive the fourth image of the workpiece from the second camera. The processor may be further configured to determine a position of the second hole in the fourth image of the workpiece relative to the first axis and the second axis to verify the position of the second hole relative to the position of the second target.

In some embodiments, the processor may be configured to verify the position of the second hole relative to the position of the second target when the second hole is centered within the second target.

In some embodiments, the first camera may be further configured to capture a fifth image of the workpiece as the stage moves relative to the first camera in the second direction after drilling the second hole in the workpiece at the position of the second target. The fifth image of the workpiece may comprise the second target and the second hole. The processor may be further configured to receive the fifth image of the workpiece from the first camera. The processor may be further configured to determine a position of the second hole in the fifth image of the workpiece relative to the first axis and the second axis to verify the position of the second hole relative to the position of the second target.

In some embodiments, the system may further comprise a second camera disposed above the stage, spaced apart from the laser beam in a second direction opposite to the first direction, and configured to capture a sixth image of the workpiece as the stage moves relative to the second camera in the first direction after drilling the first hole in the workpiece at the position of the first target. The sixth image of the workpiece may comprise the first target and the first hole. The processor may be further configured to receive the sixth image of the workpiece from the second camera. The processor may be further configured to determine a position of the first hole in the sixth image of the workpiece relative to the first axis and the second axis to verify the position of the first hole relative to the position of the first target.

In some embodiments, the first target may comprise a pad. Drilling the first hole in the workpiece at the position of the first target may produce a through-hole pad.

In some embodiments, the stage may be configured to move the workpiece along the first axis at a constant velocity.

Another embodiment of the present disclosure provides a method. The method may comprise moving, with a stage, a workpiece in a first direction along a first axis. The workpiece may include a first target defined on a surface of the workpiece. The method may further comprise capturing, with a first camera, a first image of the workpiece as the stage moves relative to the first camera in the first direction. The first image of the workpiece may comprise the first target. The method may further comprise determining, with a processor, a position of the first target in the first image of the workpiece relative to the first axis and a second axis that is orthogonal to the first axis. The method may further comprise moving a steerable mirror to direct a laser beam onto the surface of the workpiece, spaced apart from the first camera in a second direction that is opposite to the first direction, to be aligned with the position of the first target along the second axis. The method may further comprise emitting, with a laser source, the laser beam directed by the steerable mirror to drill a first hole in the workpiece at the position of the first target when the laser beam is aligned with the position of the first target along the first axis by movement of the stage in the first direction.

In some embodiments, the method may further comprise moving, with the stage, the workpiece in the second direction along the first axis after drilling the first hole in the workpiece at the position of the first target. The method may further comprise capturing, with the first camera, a second image of the workpiece as the stage moves relative to the first camera in the second direction. The second image of the workpiece may comprise the first target and the first hole. The method may further comprise determining, with the processor, a position of the first hole in the second image of the workpiece relative to the first axis and the second axis to verify the position of the first hole relative to the position of the first target.

In some embodiments, a plurality of targets may be defined on the surface of the workpiece. The first target may be one of the plurality of targets. The method may further comprise moving, with the stage, the workpiece along the second axis to align a second target of the plurality of targets with a path of the laser beam as the stage moves along the first axis.

In some embodiments, the method may further comprise moving, with the stage, the workpiece in the second direction along the first axis. The method may further comprise capturing, with a second camera, a third image of the workpiece as the stage moves relative to the second camera in the second direction. The second camera may be spaced apart from the laser beam in the second direction. The third image of the workpiece may comprise the second target. The method may further comprise determining, with the processor, a position of the second target in the third image of the workpiece relative to the first axis and the second axis. The method may further comprise moving the steerable mirror to direct the laser beam onto the surface of the workpiece spaced apart from the first camera in the second direction to be aligned with the position of the second target along the second axis. The method may further comprise emitting, with the laser source, the laser beam directed by the steerable mirror to drill a second hole in the workpiece at the position of the second target when the laser beam is aligned with the position of the second target along the first axis by movement of the stage in the second direction.

In some embodiments, the method may further comprise moving, with the stage, the workpiece in the first direction along the first axis after drilling the second hole in the workpiece at the position of the second target. The method may further comprise capturing, with the second camera, a fourth image of the workpiece as the stage moves relative to the second camera in the first direction. The fourth image of the workpiece may comprise the second target and the second hole. The method may further comprise determining, with the processor, a position of the second hole in the fourth image of the workpiece relative to the first axis and the second axis to verify the position of the second hole relative to the position of the second target.

In some embodiments, the method may further comprise capturing, with the first camera, a fifth image of the workpiece as the stage moves relative to the first camera in the second direction after drilling the second hole in the workpiece at the position of the second target. The fifth image of the workpiece may comprise the second target and the second hole. The method may further comprise determining, with the processor, a position of the second hole in the fifth image of the workpiece relative to the first axis and the second axis to verify the position of the second hole relative to the position of the second target.

In some embodiments, the method may further comprise capturing, with a second camera, a sixth image of the workpiece as the stage moves relative to the second camera in the first direction after drilling the first hole in the workpiece at the position of the first target. The second camera may be spaced apart from the laser beam in the second direction. The sixth image of the workpiece may comprise the first target and the first hole. The method may further comprise determining, with the processor, a position of the first hole in the sixth image of the workpiece relative to the first axis and the second axis to verify the position of the first hole relative to the position of the first target.

In some embodiments, the first target may comprise a pad. Drilling the first hole in the workpiece at the position of the first target may produce a through-hole pad.

### DESCRIPTION OF THE DRAWINGS

For a fuller understanding of the nature and objects of the disclosure, reference should be made to the following detailed description taken in conjunction with the accompanying drawings, in which:

FIG. 1 is a side view along a first axis of a system according to an embodiment of the present disclosure;

FIG. 2 is a side view along a second axis of the system of FIG. 1;

FIGS. 3A to 3D illustrate an exemplary laser drilling and optical inspection process using the system of FIG. 1:

FIG. 4 is a top view of the system of FIG. 1 showing a path of the laser beam in an exemplary laser drilling and inspection process;

FIG. 5 is a side view along the first axis of a system according to another embodiment of the present disclosure;

FIGS. 6A to 6D illustrate an exemplary laser drilling and optical inspection process using the system of FIG. 5;

FIG. 6E illustrates an alternative optical inspection step using the system of FIG. 5 in place of the step shown in FIG. 6D;

FIG. 7 a top view of the system of FIG. 5 showing a path of the laser beam in an exemplary laser drilling and inspection process;

FIG. 8 is a flowchart of a method according to an embodiment of the present disclosure;

FIG. 9 is a flowchart of a method according to another embodiment of the present disclosure;

FIG. 10 is a flowchart of a method according to another embodiment of the present disclosure;

FIG. 11 is a flowchart of a method according to another embodiment of the present disclosure;

FIG. 12 is a flowchart of a method according to another embodiment of the present disclosure; and

FIG. 13 is a flowchart of a method according to another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

An embodiment of the present disclosure provides a system 100. The system 100 may be configured to perform laser processing of a workpiece 101. The workpiece 101 may be, for example, a semiconductor wafer or substrate, such as a printed circuit board (PCB). The workpiece 101 may include a plurality of targets defined on a surface 102 of the workpiece 101. Each target may be a pad or pattern feature defined on the surface 102 of the workpiece 101 where a drill point should be located, not a reference marking or fiducial. A pad may be an exposed region of metal on the surface 102 of the workpiece 101 for connection to an electronic component. Drilling a hole in the workpiece 101 at the position of a target may produce a through-hole pad or other cut a pattern feature. As referenced herein, the plurality of targets may include a first target 103, a second target 104, and any number of additional targets defined on the surface 102 of the workpiece.

The system 100 may comprise a stage 110. The stage 110 may be configured to support the workpiece 101. The stage 110 may include one or more motors or actuators configured to move the workpiece 101 supported by the stage 110. For example, the stage 110 may be configured to move the workpiece 101 in one or more in-plane directions, described as movements along a first axis 111 (i.e., x-direction) and a second axis 112 (i.e., y-direction) herein. The stage 110 may be further configured to move the workpiece 101 in one or more out-of-plane directions (i.e., z-direction).

The system 100 may further comprise a first camera 120. The first camera 120 may be disposed above the stage 110. The first camera 120 may be a charge coupled device (CCD) camera, complementary metal oxide semiconductor (CMOS) camera, or other type of camera having an appropriate lens and number of pixels for the particular application. The first camera 120 may be configured to capture one or more images of the workpiece 101 as the stage 110 moves relative to the first camera 120 along the first axis 111. Each image of the workpiece 101 captured by the first camera 120 may include a portion of the surface 102 of the workpiece 101 located within a field of view 121 of the first camera 120. For example, each image of the workpiece 101 may include one or more of the plurality of targets defined on the surface 102 of the workpiece 101 (e.g., the first target 103 or the second target 104), depending on the number of targets visible within the field of view 121 of the first camera 120.

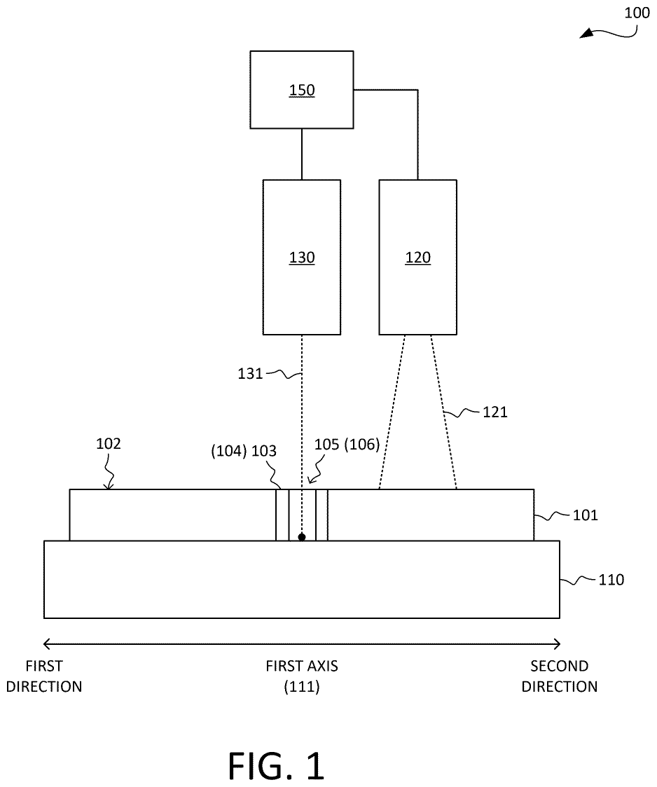

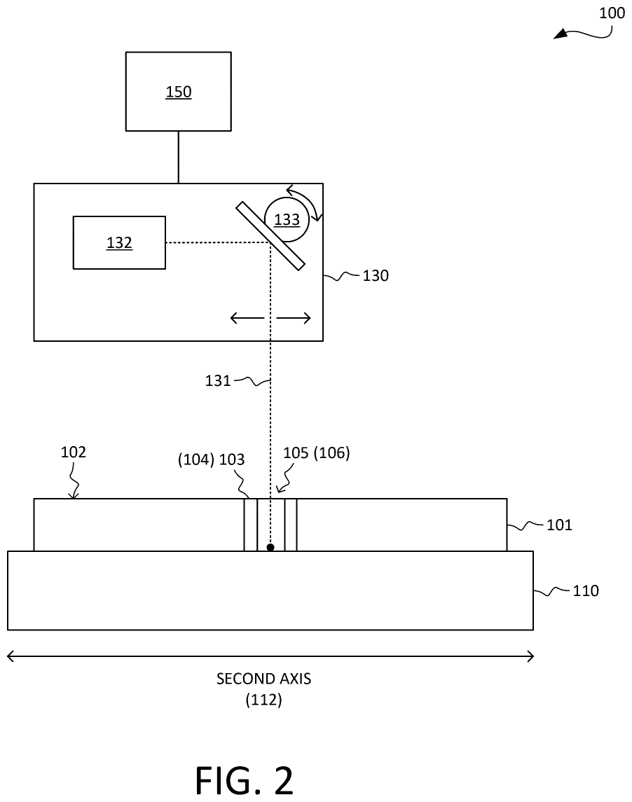

The system 100 may further comprise a processing head 130. The processing head 130 may be spaced apart from, or adjacent to, the first camera 120 in the first direction along the first axis 111, as shown in FIG. 1. As further shown in FIG. 2, the processing head 130 may include a laser source 132 configured to emit a laser beam 131 and a steerable mirror 133 configured to direct the laser beam 131 onto the surface 102 of the workpiece 101. The laser beam 131 may have a diameter in the range of tens of microns. The laser beam 131 may have a wavelength within the ultra-violet (UV) to far infrared (IR) spectral range. The steerable mirror 133 may be movable to direct the laser beam 131 along the second axis 112 to adjust where the laser beam 131 impacts the surface 102 of the workpiece 101 relative to the second axis. The steerable mirror 133 may be a fast-steering mirror, galvo mirror, acousto-optical deflector (AOD), micro electro-mechanical system (MEMS) mirror, or other type of movable mirror assembly.

The system 100 may further comprise a processor 150. The processor 150 may include a microprocessor, a microcontroller, or other devices. The processor 150 may be coupled to the components of the system 100 in any suitable manner (e.g., via one or more transmission media, which may include wired and/or wireless transmission media) such that the processor 150 can receive output. The processor 150 may be configured to perform a number of functions using the output. An inspection tool can receive instructions or other information from the processor 150. The processor 150 optionally may be in electronic communication with another inspection tool, a metrology tool, a repair tool, or a review tool (not illustrated) to receive additional information or send instructions.

The processor 150 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 150 may be disposed in or otherwise part of the system 100 or another device. In an example, the processor 150 may be part of a standalone control unit or in a centralized quality control unit. Multiple processors 150 may be used, defining multiple subsystems of the system 100.

The processor 150 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 150 to implement various methods and functions may be stored in readable storage media, such as a memory.

If the system 100 includes more than one subsystem, then the different processors 150 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 150 may be configured to perform a number of functions using the output of the system 100 or other output. For instance, the processor 150 may be configured to send the output to an electronic data storage unit or another storage medium. The processor 150 may be further configured as described herein.

The processor 150 may be configured according to any of the embodiments described herein. The processor 150 also may be configured to perform other functions or additional steps using the output of the system 100 or using images or data from other sources.

The processor 150 may be communicatively coupled to any of the various components or sub-systems of system 100 in any manner known in the art. Moreover, the processor 150 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 150 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 150 (or computer subsystem) or, alternatively, multiple processors 150 (or multiple computer subsystems). Moreover, different sub-systems of the system 100 may include one or more computing or logic systems. Therefore, the above description should not be interpreted as a limitation on the present disclosure but merely an illustration.

The processor 150 may be in electronic communication with the stage 110. For example, the processor 150 may be configured to send instructions to the one or more motors or actuators of the stage 110 to move the workpiece 101 relative to the first camera 120 and the processing head 130 along the first axis 111 and the second axis 112. The stage 110 may be configured to move the workpiece 101 relative to the first camera 120 at a constant velocity. Alternatively, the stage 110 may be configured to move the workpiece 101 relative to the first camera 120 in a stop/start process where the stage 110 stops moving to perform each laser processing and optical inspection step described below.

The processor 150 may be in electronic communication with the first camera 120. For example, the processor 150 may be configured to send instructions to the first camera 120 to capture one or more images of the workpiece 101 as the stage 110 moves the workpiece 101 relative to the first camera 120. The processor 150 may be further configured to receive the one or more images of the workpiece 101 captured by the first camera 120. The processor 150 may be configured to identify features in the images of the workpiece 101 received from the first camera 120. For example, the processor 150 may identify the first target 103 or the second target 104 (e.g., an outline of the first target 103 or the second target 104) in the image of the workpiece 101 using image processing, and the processor 150 can determine a center point of the first target 103 or the second target 104, the coordinates of which may correspond to the position of the first target 103 or the second target 104 in the image of the workpiece 101. In some embodiments, the processor 150 may further identify any other pattern features (in addition to the first target 103 or the second target 104) present in the image of the workpiece 101 and calculate the coordinates of each feature in a similar manner.

The processor 150 may be in electronic communication with the steerable mirror 133. For example, the processor 150 maybe configured to send instructions to the one or more motors or actuators of the steerable mirror 133 to move the steerable mirror 133 to direct the laser beam 131 onto the surface 102 of the workpiece 101. For example, based on a known position of the stage 110 relative to the second axis 112, the processor 150 can send instructions to move the steerable mirror 133 to move to direct the laser beam 131 onto the surface 102 of the workpiece 101 to be aligned with the position of the first target 103 or the second target 104 along the second axis 112.

The processor 150 may be in electronic communication with the laser source 132. For example, the processor 150 may be configured to send instructions to the laser source 132 to emit the laser beam 131 to be directed by the steerable mirror 133 onto the surface 102 of the workpiece 101 when the laser beam 131 is aligned with the position of the first target 103 or the second target 104 along the first axis 111. Directing the laser beam 131 onto the surface 102 of the workpiece 101, the laser beam 131 can drill a first hole 105 in the first target 103 or a second hole 106 in the second target 104. In other words, after aligning the laser beam 131 with the position of the first target 103 or the second target 104 along the second axis 112 using the steerable mirror 133, the movement of the stage 110 along the first axis 111 aligns the laser beam 131 with the position of the first target 103 or the second target 104 along the first axis 111. Accordingly, the laser beam 131 can be used to drill the first hole 105 in the first target 103 and the second hole 106 in the second target 104 with accurate placement, without risk of misalignment due to local distortion of the workpiece 101.

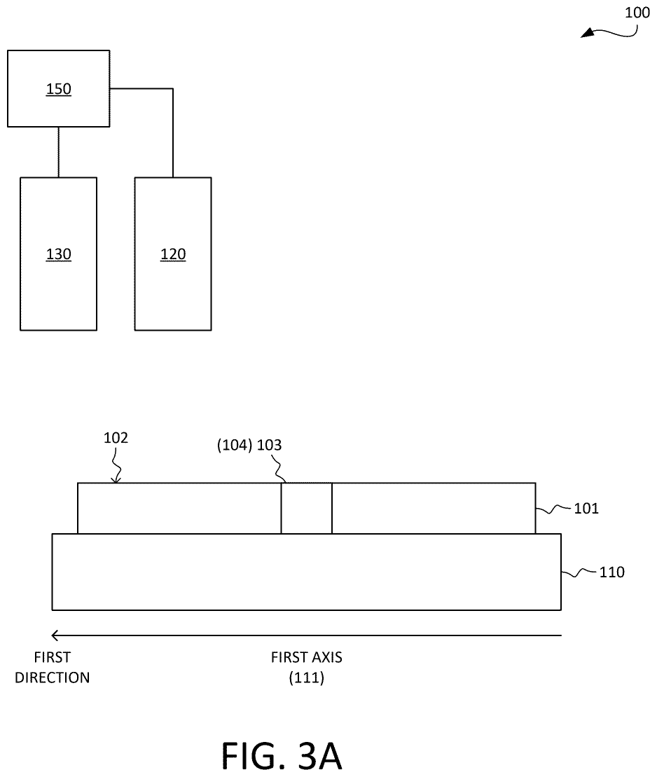

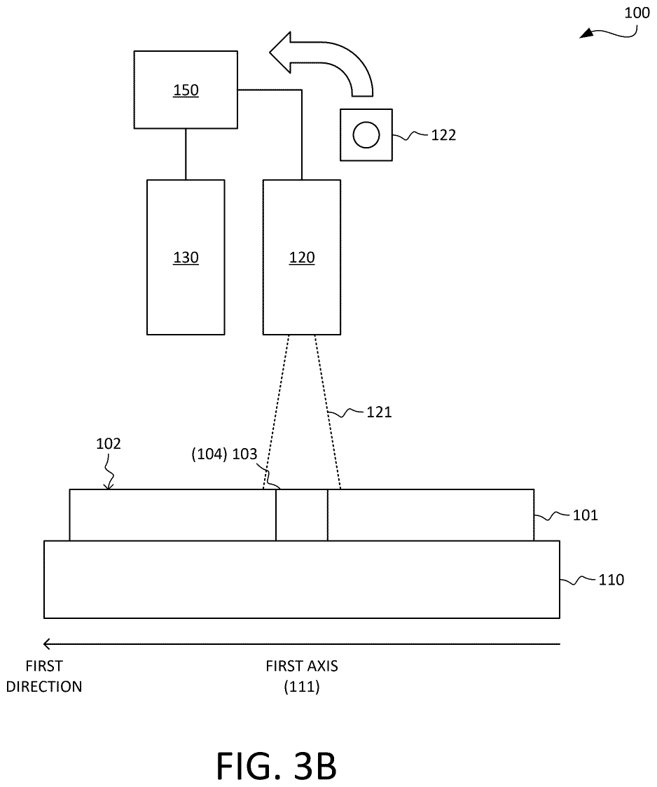

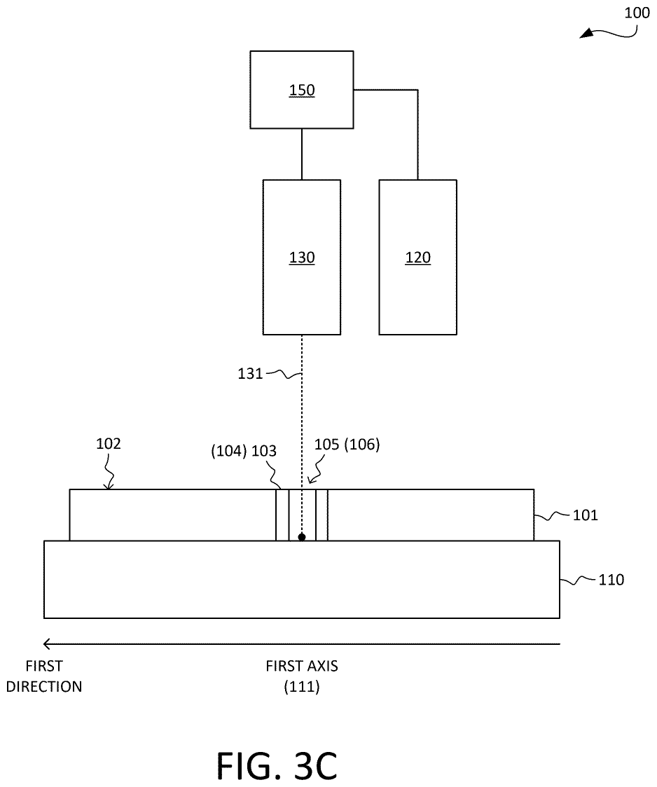

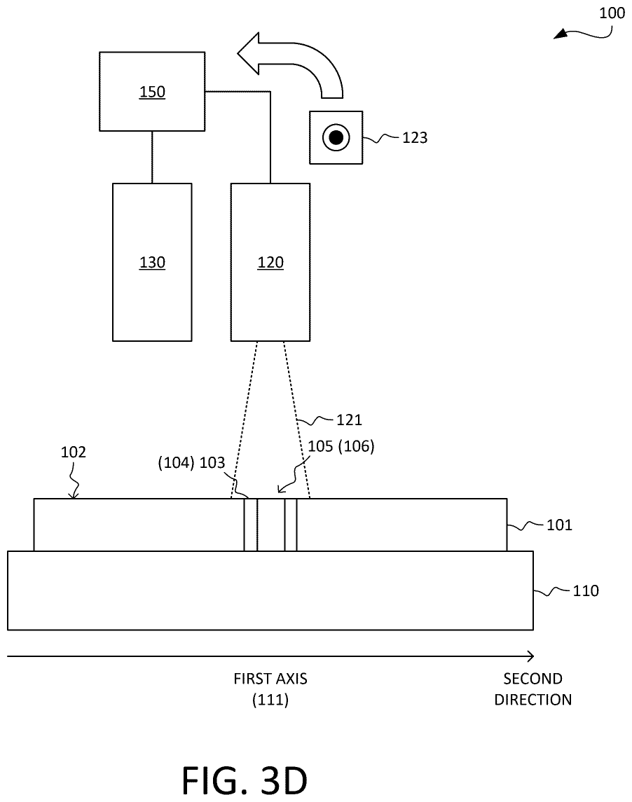

FIGS. 3A to 3C illustrate an exemplary laser drilling process performed using the system 100 described herein to drill the first hole 105 in the first target 103 of the workpiece 101. As shown in FIG. 3A, the stage 110 first moves the workpiece 101 in the first direction along the first axis 111. When the first target 103 enters the field of view 121 of the first camera 120, the first camera 120 may capture a first image 122 of the workpiece 101, as shown in FIG. 3B. The first image 122 of the workpiece 101 may comprise the first target 103. The processor 150 may receive the first image 122 of the workpiece 101 from the first camera 120 and may determine the position of the first target 103 in the first image 122 relative to the first axis 111 and the second axis 112. Based on the position of the first target 103, the processor 150 may send instructions to the steerable mirror 133 to move the laser beam 131 to align with the position of the first target 103 along the second axis 112. When the laser beam 131 is aligned with the position of the first target 103 along the first axis 111 by movement of the stage 110 in the first direction, the processor 150 can further send instructions to the laser source 132 to emit the laser beam 131 to drill the first hole 105 in the workpiece 101 at the position of the first target 103, as shown in FIG. 3C. Accordingly, the laser beam 131 can be used to drill the first hole 105 in the first target 103 with accurate placement, without risk of misalignment due to local distortion of the workpiece 101.

As further shown in FIG. 3D, an optical inspection process can be performed following the laser drilling process of FIGS. 3A to 3C. For example, the stage 110 can reverse to move the workpiece 101 in the second direction along the first axis 111 to perform the optical inspection process following the laser drilling process. When the first target 103 re-enters the field of view 121 of the first camera 120, the first camera 120 may capture a second image 123 of the workpiece 101. The second image 123 of the workpiece 101 may comprise the first target 103 and the first hole 105. The processor 150 may receive the second image 123 of the workpiece 101 from the first camera 120 and may determine a position of the first hole 105 in the second image 123 relative to the first axis 111 and the second axis 112 to verify the position of the first hole 105 relative to the first target 103. For example, the processor 150 may identify the first hole 105 within the second image 123 (e.g., an outline of the first hole 105) using image processing, and the processor 150 can verify the position of the first hole 105 relative to the position of the first target 103 using the outline of the first target 103 or the coordinates of the center point of the first target 103. For example, the position of the first hole 105 can be verified if the outline of the first hole 105 falls within the outline of the first target 103 or if the first hole 105 is centered within the first target 103. Accordingly, automatic optical inspection of the first target 103 can be performed after drilling, without transferring the workpiece 101 to a separate inspection station.

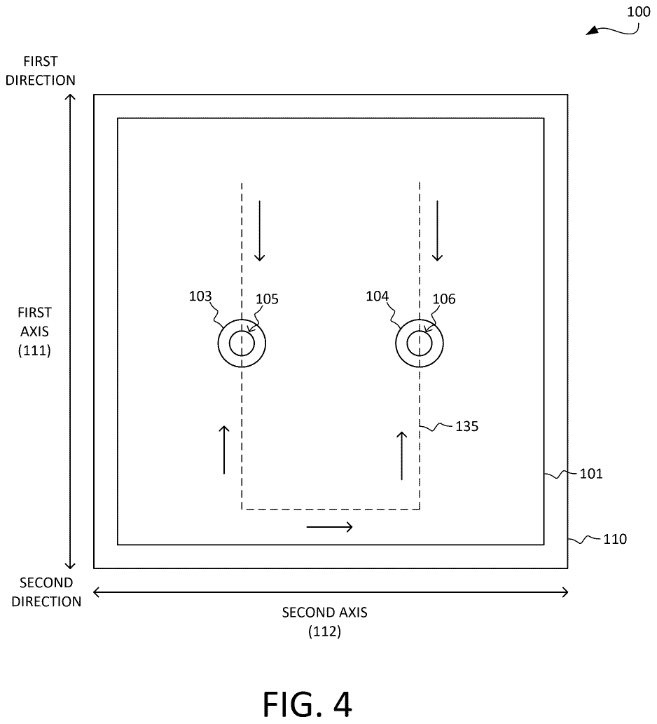

The exemplary laser drilling and optical inspection process shown in FIGS. 3A to 3D can be repeated across the surface 102 of the workpiece 101. For example, the stage 110 can move the workpiece 101 along the second axis 112 to index the workpiece 101 and align the second target 104 with a path 135 of the laser beam 131 as the stage moves along the first axis 111, as shown in FIG. 4. The workpiece 101 can be further indexed along the second axis 112 for further drilling operations of additional targets of the workpiece 101. For example, the exemplary laser drilling and optical inspection process may include a periodic movement process of scanning the workpiece 101 in the first direction along the first axis 111 for drilling the first hole 105 and then scanning the workpiece 101 in the second direction along the first axis 111 for optical inspection of the first hole 105, followed by indexing movement along the second axis 112 to perform the same steps for drilling and optical inspection of the second hole 106, as shown in FIG. 4.

It should be understood that although the exemplary laser drilling and optical inspection process of FIGS. 3A to 3D is shown for a single hole drilled in a single target of the workpiece, it should be understood that the system 100 may drill and inspect several holes in the workpiece 101 (e.g., targets located before and after the first target 103 or the second target 104 along the path 135 of the laser beam 131 shown in FIG. 4) in sequence through movement of the stage 110 along the first axis 111, with alignment of the laser beam 131 by adjusting the steerable mirror 133 after capturing an image of each target prior to drilling.

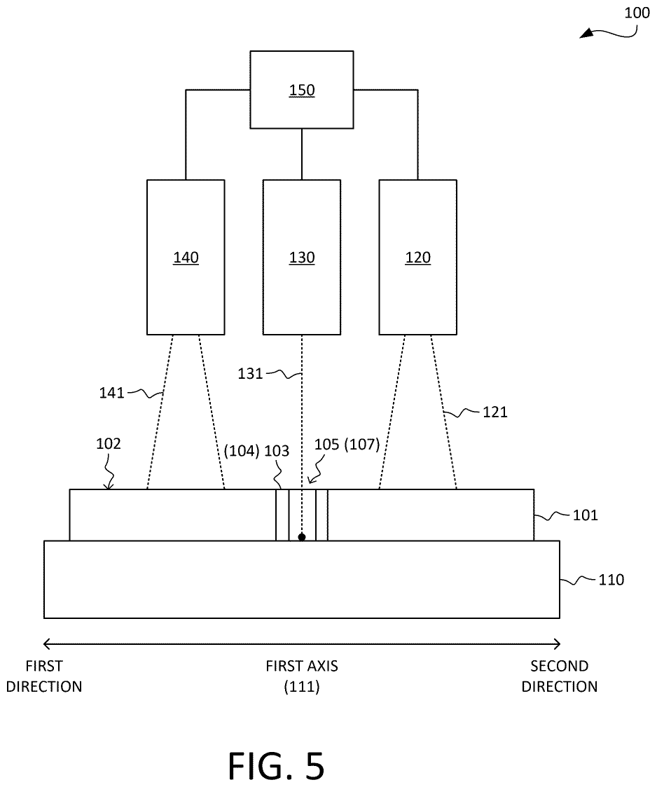

In some embodiments, the system 100 may further comprise a second camera 140, as shown in FIG. 5. The second camera 140 may be disposed above the stage 110. The second camera 140 may be a charge coupled device (CCD) camera, complementary metal oxide semiconductor (CMOS) camera, or other type of camera having an appropriate lens and number of pixels for the particular application. In some embodiments, the second camera 140 may be identical or similar to the first camera 120. The second camera 140 may be configured to capture one or more images of the workpiece 101 as the stage 110 moves relative toe the second camera 140 along the first axis 111. Each image of the workpiece 101 captured by the second camera 140 may include a portion of the surface 102 of the workpiece 101 located within the field of view 141 of the second camera 140. For example, each image of the workpiece 101 may include one or more of the plurality of targets defined on the surface 102 of the workpiece 101 (e.g., the first target 103 or the second target 104), depending on the number of targets visible within the field of view 141 of the second camera 140.

The second camera 140 may be spaced apart from, or adjacent to, the processing head 130 in the first direction along the first axis 111. In other words, the first camera 120 and the second camera 140 may be disposed on opposite sides of the processing head 130. Accordingly, the first camera 120 may be leading when the stage 110 moves the workpiece 101 in the first direction along the first axis 111, and the second camera 140 may be leading when the stage 110 moves the workpiece 101 in the second direction along the first axis 111, which can allow for one camera to be used for alignment before drilling with the stage 110 moving in either direction. In addition, the other (trailing) camera can be used for optical inspection after drilling, without reversing the movement direction of the stage 110.

The processor 150 may be in electronic communication with the second camera 140. For example, the processor 150 may be configured to send instructions to the second camera 140 to capture one or more images of the workpiece 101 as the stage 110 moves the workpiece 101 relative to the second camera 140. The processor 150 may be further configured to receive the one or more images of the workpiece 101 captured by the second camera 140. The processor 150 may be configured to identify features in the images of the workpiece 101 received from the second camera 140. For example, the processor 150 may identify the first target 103 or the second target 104 (e.g., an outline of the first target 103 or the second target 104) in the image of the workpiece 101 using image processing, and the processor 150 can determine a center point of the first target 103 or the second target 104, the coordinates of which may correspond to the position of the first target 103 or the second target 104 in the image of the workpiece 101.

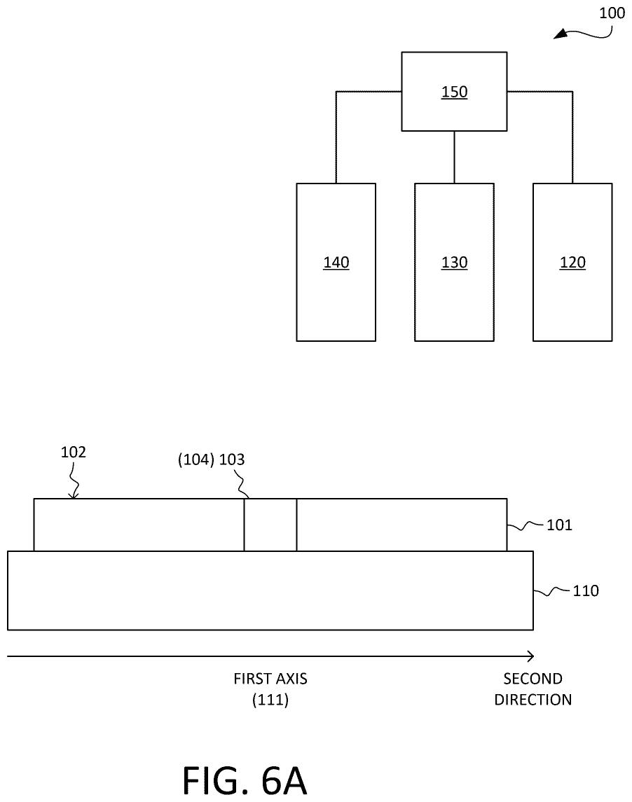

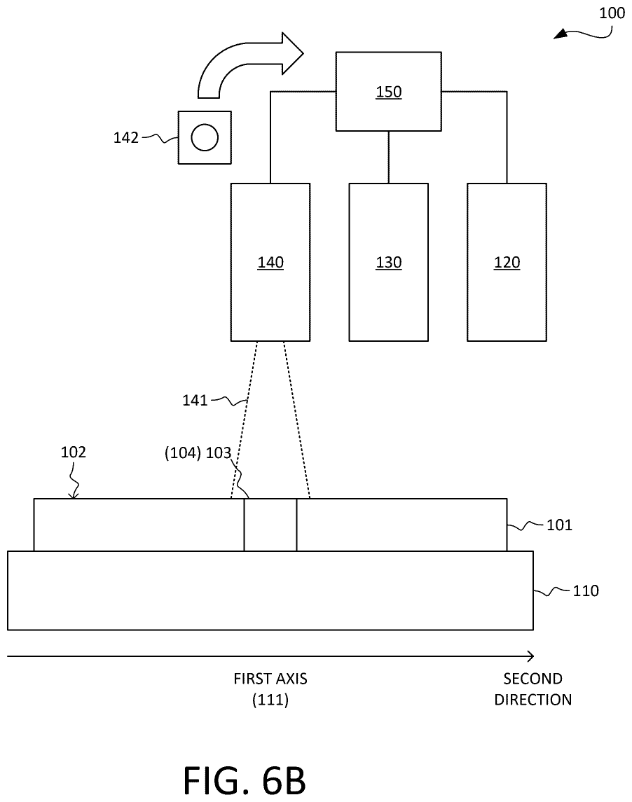

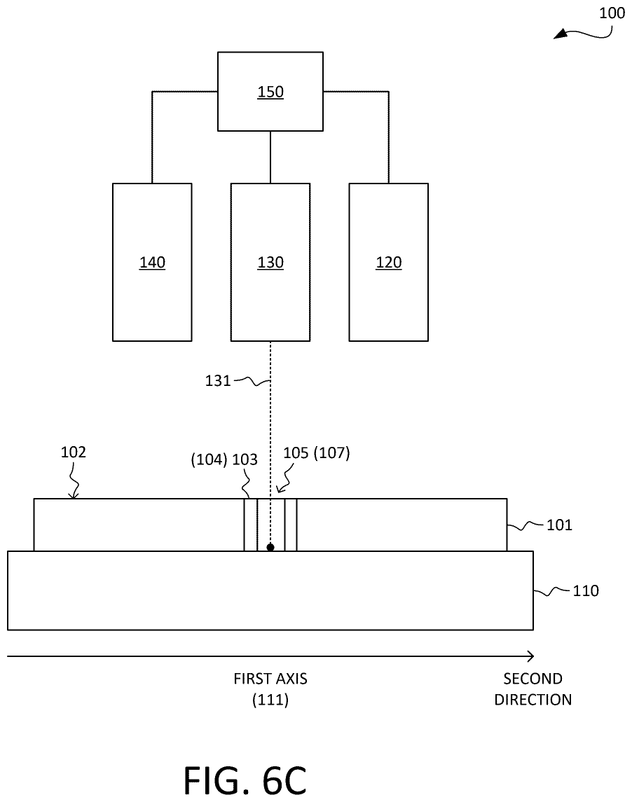

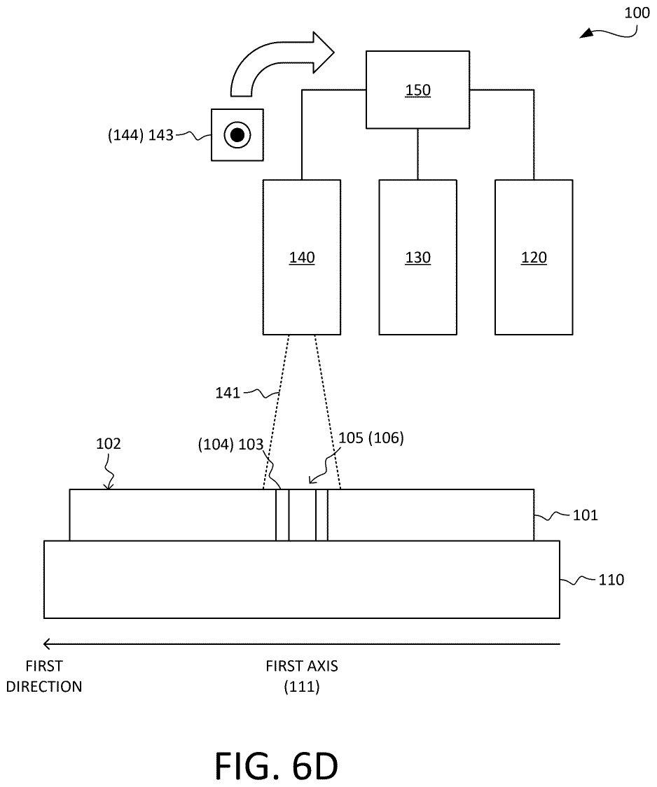

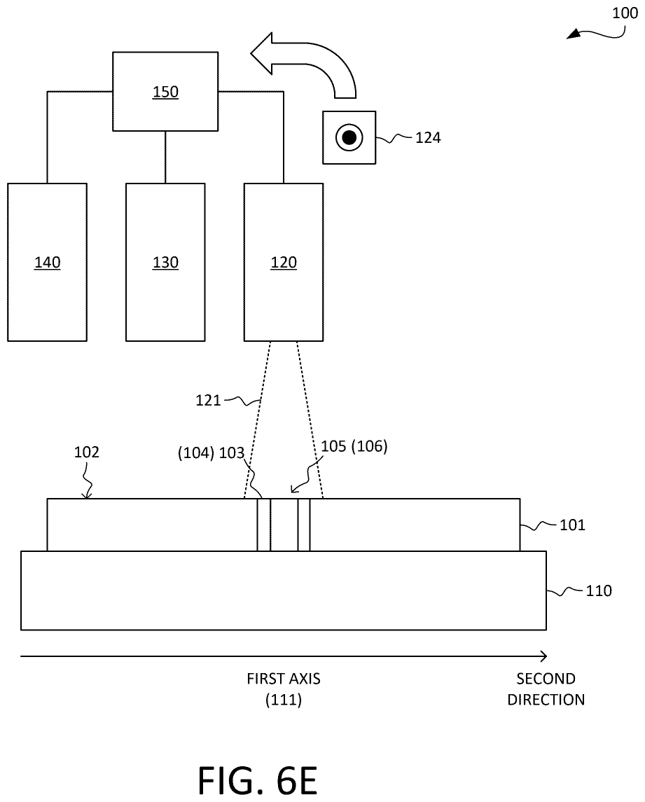

FIGS. 6A to 6C illustrate an exemplary laser drilling process performed using the system 100 described herein to drill the first hole 105 in the first target 103 of the workpiece 101. The process of FIGS. 6A to 6C is similar to that of FIGS. 3A to 3C described above, but relies on the second camera 140 to allow movement of the stage 110 in the opposite direction. As shown in FIG. 6A, the stage 110 first moves the workpiece 101 in the second direction along the first axis 111. When the first target 103 enters the field of view 141 of the second camera 140, the second camera 140 may capture a third image 142 of the workpiece 101, as shown in FIG. 6B. The third image 142 of the workpiece 101 may comprise the first target 103. The processor 150 may receive the third image 142 of the workpiece 101 from the second camera 140 and may determine the position of the first target 103 in the third image 142 relative to the first axis 111 and the second axis 112. Based on the position of the first target 103, the processor 150 may send instructions to the steerable mirror 133 to move the laser beam 131 to align with the position of the first target 103 along the second axis 112. When the laser beam 131 is aligned with the position of the first target 103 along the first axis 111 by movement of the stage 110 in the second direction, the processor 150 can further send instructions to the laser source 132 to emit the laser beam 131 to drill the first hole 105 in the workpiece 101 at the position of the first target 103, as shown in FIG. 6C. Accordingly, the laser beam 131 can be used to drill the first hole 105 in the first target 103 with accurate placement, without risk of misalignment due to local distortion of the workpiece 101.

As further shown in FIG. 6D, an optical inspection process can be performed following the laser drilling process of FIGS. 6A to 6C, similar to the process shown in FIG. 3D. For example, the stage 110 can reverse to move the workpiece 101 in the first direction along the first axis 111. When the first target 103 re-enters the field of view 141 of the second camera 140, the second camera 140 may capture a fourth image 143 of the workpiece 101. The fourth image 143 of the workpiece 101 may comprise the first target 103 and the first hole 105. The processor 150 may receive the fourth image 143 of the workpiece 101 from the second camera 140 and may determine a position of the first hole 105 in the fourth image 143 relative to the first axis 111 and the second axis 112 to verify the position of the first hole 105 relative to the first target 103. For example, the processor 150 may identify the first hole 105 within the fourth image 143 (e.g., an outline of the first hole 105) using image processing, and the processor 150 can verify the position of the first hole 105 relative to the position of the first target 103 using the outline of the first target 103 or the coordinates of the center point of the first target 103. For example, the position of the first hole 105 can be verified if the outline of the first hole 105 falls within the outline of the first target 103 or if the first hole 105 is centered within the first target 103. Accordingly, automatic optical inspection of the first target 103 can be performed after drilling, without transferring the workpiece 101 to a separate inspection station.

Alternatively, the optical inspection process can be performed using the first camera 120, as shown in FIG. 6E. For example, after the laser drilling process of FIGS. 6A to 6C, the stage 110 can continue to move the workpiece 101 in the second direction along the first axis 111. When the first target 103 enters the field of view 121 of the first camera 120, the first camera 120 may capture a fifth image 124 of the workpiece 101. The fifth image 124 of the workpiece 101 may comprise the first target 103 and the first hole 105. The processor 150 may receive the fifth image 124 of the workpiece 101 from the first camera 120 and may determine a position of the first hole 105 in the fifth image 124 relative to the first axis 111 and the second axis 112 to verify the position of the first hole 105 relative to the first target 103. For example, the processor 150 may identify the first hole 105 within the fifth image 124 (e.g., an outline of the first hole 105) using image processing, and the processor 150 can verify the position of the first hole 105 relative to the position of the first target 103 using the outline of the first target 103 or the coordinates of the center point of the first target 103. For example, the position of the first hole 105 can be verified if the outline of the first hole 105 falls within the outline of the first target 103 or if the first hole 105 is centered within the first target 103. Accordingly, automatic optical inspection of the first target 103 can be performed after drilling, without transferring the workpiece 101 to a separate inspection station, and without reversing the direction of the stage 110.

Similarly, the optical inspection process of FIG. 6D using the second camera 140 can be performed in place of the optical inspection process of FIG. 3D. For example, after the laser drilling process of FIGS. 3A to 3C, the stage 110 can continue to move the workpiece 101 in the first direction along the first axis 111. When the first target 103 enters the field of view 141 of the second camera 140, the second camera 140 may capture a sixth image 144 of the workpiece 101. The sixth image 144 of the workpiece 101 may comprise the first target 103 and the first hole 105. The processor 150 may receive the sixth image 144 of the workpiece 101 from the second camera 140 and may determine a position of the first hole 105 in the sixth image 144 relative to the first axis 111 and the second axis 112 to verify the position of the first hole 105 relative to the first target 103. For example, the processor 150 may identify the first hole 105 within the sixth image 144 (e.g., an outline of the first hole 105) using image processing, and the processor 150 can verify the position of the first hole 105 relative to the position of the first target 103 using the outline of the first target 103 or the coordinates of the center point of the first target 103. For example, the position of the first hole 105 can be verified if the outline of the first hole 105 falls within the outline of the first target 103 or if the first hole 105 is centered within the first target 103. Accordingly, automatic optical inspection of the first target 103 can be performed after drilling, without transferring the workpiece 101 to a separate inspection station, and without reversing the direction of the stage 110.

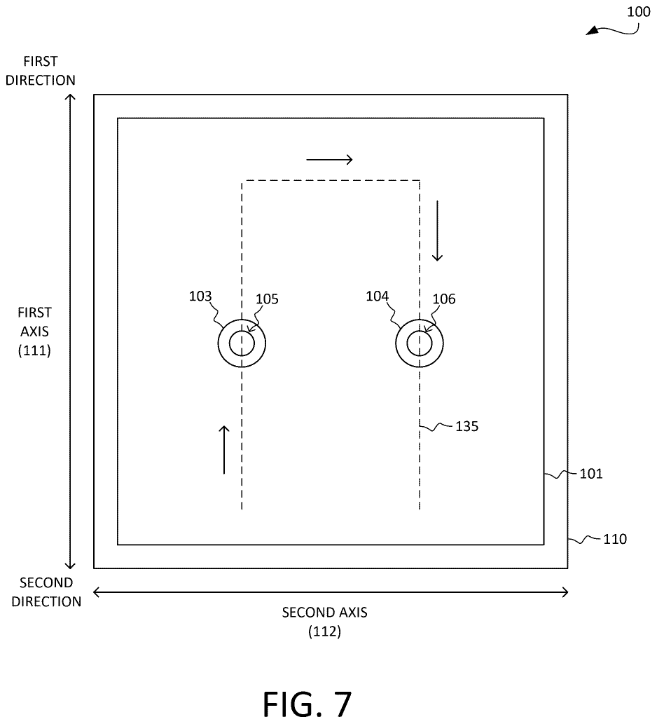

The exemplary laser drilling and optical inspection process shown in FIGS. 6A to 6C and 6E can be repeated across the surface 102 of the workpiece 101. For example, the stage 110 can move the workpiece 101 along the second axis 112 to index the workpiece 101 and align the second target 104 with a path 135 of the laser beam 131 as the stage moves along the first axis 111, as shown in FIG. 7. The workpiece 101 can be further indexed along the second axis 112 for further drilling operations of additional targets of the workpiece 101. For example, the exemplary laser drilling and optical inspection process may include a snaking movement process of scanning the workpiece 101 in the first direction along the first axis 111 for drilling and optical inspection of the first hole 105, followed by indexing movement along the second axis 112 to perform the same steps for drilling and optical inspection of the second hole 106 by scanning the workpiece 101 in the second direction along the first axis, as shown in FIG. 7.

It should be understood that although the exemplary laser drilling and optical inspection process of FIGS. 6A to 6D is shown for a single hole drilled in a single target of the workpiece, it should be understood that the system 100 may drill and inspect several holes in the workpiece 101 (e.g., targets located before and after the first target 103 or the second target 104 along the path 135 of the laser beam 131 shown in FIG. 7) in sequence through movement of the stage 110 along the first axis 111, with alignment of the laser beam 131 by adjusting the steerable mirror 133 after capturing an image of each target prior to drilling.

In some embodiments, the system 100 may comprise a plurality of processing heads 130, each having a first camera 120 and/or a second camera 140 adjacent thereto. Accordingly, the system 100 may be configured to perform laser drilling and optical inspection simultaneously for a plurality of targets of the workpiece 101, with each processing head 130 being separately aligned with a respective target for accurate cutting alignment.

With the system 100, the laser beam can be directly aligned with each target of the workpiece (rather than alignment based on coordinate transformation from fiducials of the workpiece), which can improve the accuracy of drilling holes at the position of each target despite local distortion of the workpiece. In addition, the cameras can be used for automatic optical inspection of each drilled hole through the drilling process, without transferring the workpiece to a separate inspection station. Accordingly, the number of defective (i.e., misaligned) holes drilled in the workpiece can be reduced, and overall throughput can be increased. Post-drilling inspection information can also be used for correction of system drifts while processing the same workpiece 101, which can improve system accuracy.

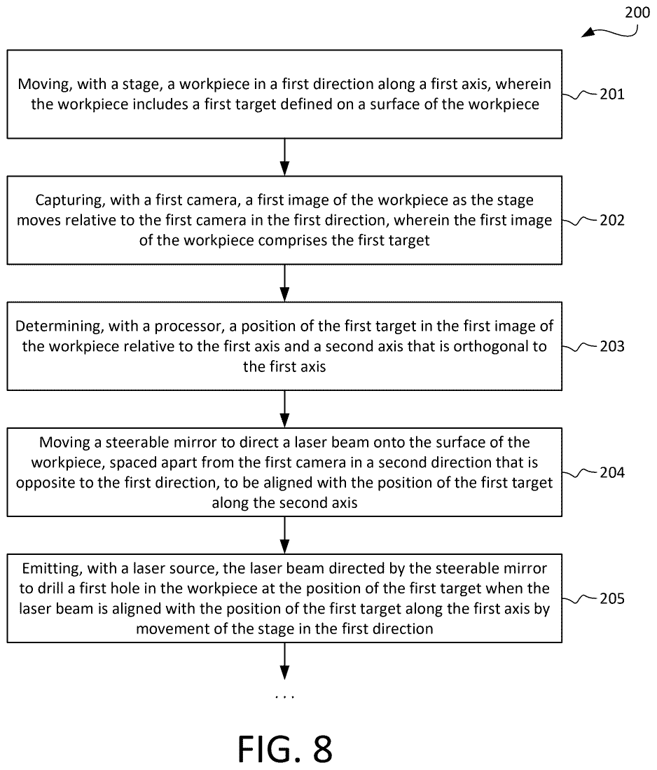

Another embodiment of the present disclosure provides a method 200. As shown in FIG. 8, the method 200 may comprise the following steps.

At step 201, a stage moves a workpiece in a first direction along a first axis. The workpiece may include a first target defined on a surface of the workpiece. The workpiece may be, for example, a semiconductor wafer or substrate, such as a printed circuit board. The target may be a pad or pattern feature where a drill point should be located, not a reference marking or fiducial. A pad may be an exposed region of metal on the surface of the workpiece for connection to an electronic component. A plurality of targets may be defined on the surface of the workpiece, with the first target being one of the plurality of targets.

At step 202, a first camera captures a first image of the workpiece as the stage moves relative to the first camera in a first direction along the first axis. The first camera may be disposed above the stage. The first image may comprise the first target. In other words, the stage may move the workpiece relative to the first camera in the first direction along the first axis, such that the first target enters a field of view of the first camera.

At step 203, a processor determines a position of the first target in the first image of the workpiece relative to the first axis and a second axis that is orthogonal to the first axis. For example, the processor may identify the first target within the first image (e.g., an outline of the first target) using image processing, and the processor can determine a center point of the first target, the coordinates of which relative to the first axis and the second axis may correspond to the position of the first target in the first image of the workpiece.

At step 204, a steerable mirror moves to direct a laser beam onto the surface of the workpiece, spaced apart from the first camera in a second direction that is opposite to the first direction, to be aligned with the position of the first target along the second axis. For example, based on a known position of the stage relative to the second axis, the steerable mirror can move to direct the laser beam onto the surface of the workpiece to be aligned with the position of the first target along the second axis.

At step 205, a laser source emits a laser beam directed by the steerable mirror to drill a first hole in the workpiece at the position of the first target when the laser beam is aligned with the position of the first target along the first axis by movement of the stage in the first direction. In other words, after aligning the laser beam with the position of the first target along the second axis using the steerable mirror, the movement of the stage in the first direction along the first axis aligns the laser beam with the position of the first target along the first axis. Accordingly, the laser beam can be used to drill the first hole in the first target with accurate placement, without risk of misalignment due to local distortion of the workpiece.

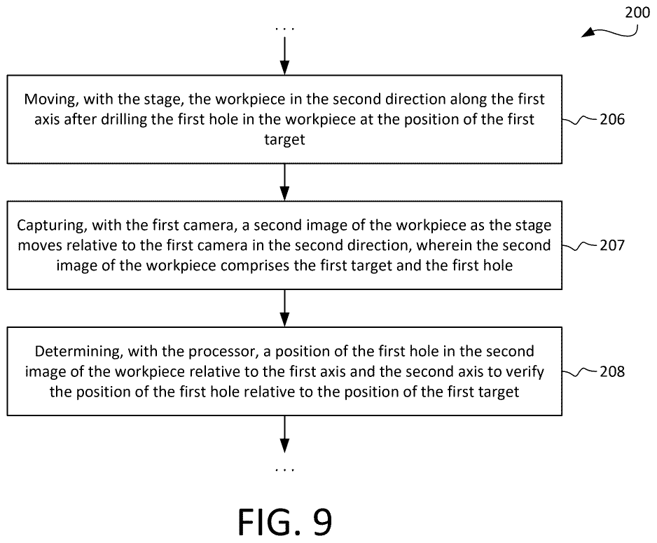

In some embodiments, the method 200 may further comprise the following steps performed after step 205, as shown in FIG. 9.

At step 206, the stage moves the workpiece in the second direction along the first axis after drilling the first hole in the workpiece at the position of the target.

At step 207, the first camera captures a second image of the workpiece as the stage moves relative to the first camera in the second direction. The second image may comprise the first target and the first hole. In other words, the stage may move the workpiece relative to the first camera in reverse direction along the first axis, such that the first target re-enters the field of view of the first camera, now having the first hole drilled therein.

At step 208, the processor determines a position of the first hole in the second image of the workpiece relative to the first axis and the second axis to verify the position of the first hole relative to the position of the first target. For example, the processor may identify the first hole within the second image (e.g., an outline of the first hole) using image processing, and the processor can verify the position of the first hole relative to the position of the first target using the outline of the first target or the coordinates of the center point of the first target. For example, the position of the first hole can be verified if the outline of the first hole falls within the outline of the first target or if the first hole is centered within the first target. Accordingly, automatic optical inspection of the first target can be performed after drilling, without transferring the workpiece to a separate inspection station.

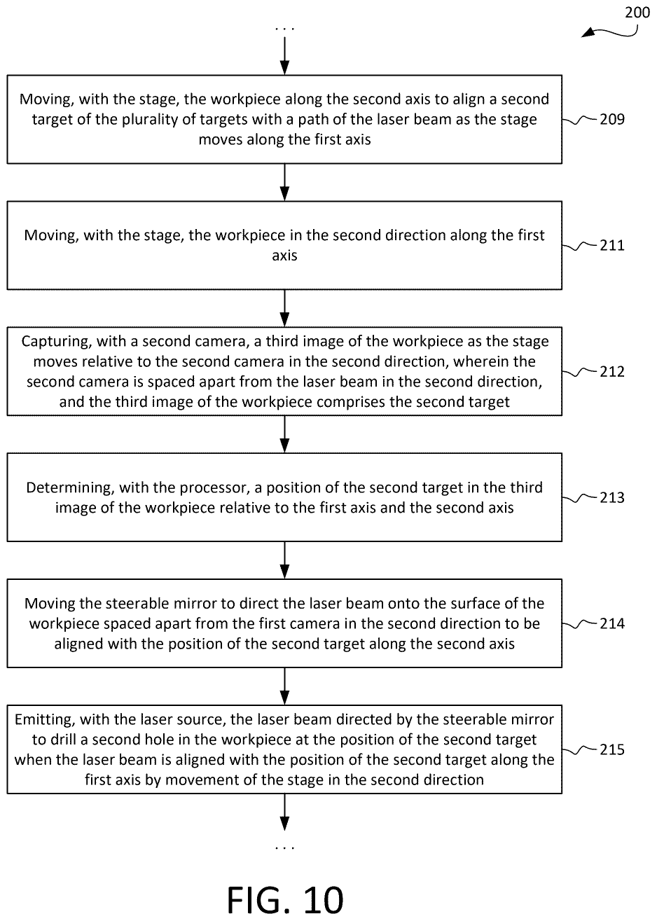

In some embodiments, the method 200 may further comprise step 209 performed after step 205, as shown in FIG. 10.

At step 209, the stage moves the workpiece along the second axis to align a second target defined on the surface of the workpiece with a path of the laser beam as the stage moves along the first axis. In other words, after scanning the workpiece in the first direction along the first axis to drill the first hole at the position of the first target of the workpiece through step 201 to step 205, the workpiece can be indexed along the second axis for further drilling operations of additional targets of the workpiece.

In some embodiments, the method may repeat steps 201 to 208 to scan the workpiece in the first direction along the first axis for drilling the first hole and in the second direction along the first axis for optical inspection of the first hole, followed by step 209, to drill each target of the workpiece in a periodic movement process.

In some embodiments, the method 200 may further comprise the following steps performed after step 209, as further shown in FIG. 10, which describe the steps of drilling a second hole and are similar to those of the first hole described above in steps 201 to 205, but are in the reverse direction (i.e., second direction).

At step 211, the stage moves the workpiece in the second direction along the first axis. In other words, after indexing the workpiece along the second axis, the workpiece can be moved in the reverse direction to scan the workpiece in the second direction.

At step 212, a second camera captures a third image of the workpiece as the stage moves relative to the second camera in the second direction. The second camera may be disposed above the stage and spaced apart from the laser beam in the second direction, such that the first camera and the second camera may be disposed on opposite sides of the laser beam along the first axis. Accordingly, the first camera may be leading when the stage moves the workpiece in the first direction along the first axis, and the second camera may be leading when the stage moves the workpiece in the second direction along the first axis. The second image may comprise the second target. In other words, the stage may move the workpiece relative to the second camera in the second direction along the first axis, such that the second target enters a field of view of the second camera.

At step 213, the processor determines a position of the second target in the third image of the workpiece relative to the first axis and the second axis. For example, the processor may identify the second target within the third image (e.g., an outline of the second target) using image processing, and the processor can determine a center point of the second target, the coordinates of which relative to the first axis and the second axis may correspond to the position of the second target in the third image of the workpiece.

At step 214, the steerable mirror moves to direct a laser beam onto the surface of the workpiece, spaced apart from the second camera in the first direction, to be aligned with the position of the second target along the second axis. For example, based on a known position of the stage relative to the second axis, the steerable mirror can move to direct the laser beam onto the surface of the workpiece to be aligned with the position of the second target along the second axis.

At step 215, the laser source emits a laser beam directed by the steerable mirror to drill a second hole in the workpiece at the position of the second target when the laser beam is aligned with the position of the second target along the first axis by movement of the stage in the second direction. In other words, after aligning the laser beam with the position of the second target along the second axis using the steerable mirror, the movement of the stage in the second direction along the first axis aligns the laser beam with the position of the second target along the first axis. Accordingly, the laser beam can be used to drill the second hole in the first target with accurate placement, without risk of misalignment due to local distortion of the workpiece.

In some embodiments, the method 200 may repeat steps 201 to 205 and steps 211 to 215 to scan the workpiece back and forth along the first axis, with step 209 being repeated each cycle therebetween, to drill each target of the workpiece in a snaking movement process.

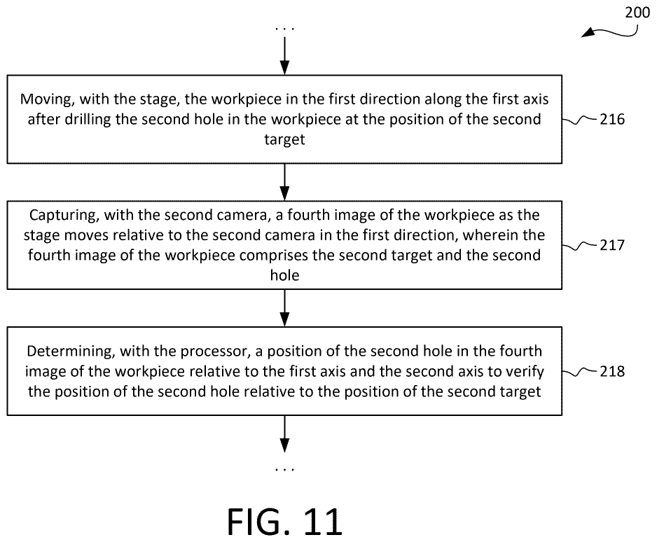

In some embodiments, the method 200 may further comprise the following steps performed after step 215, as shown in FIG. 11, which describe the steps of optical inspection of the second hole and are similar to those of the first hole described above in steps 206 to 208, but are in the reverse direction (i.e., the first direction).

At step 216, the stage moves the workpiece in the first direction along the first axis after drilling the second hole in the workpiece at the position of the second target.

At step 217, the second camera captures a fourth image of the workpiece as the stage moves relative to the second camera in the first direction. The fourth image may comprise the second target and the second hole. In other words, the stage may move the workpiece relative to the second camera in reverse direction along the first axis, such that the second target re-enters the field of view of the second camera, now having the second hole drilled therein.

At step 218, the processor determines a position of the second hole in the fourth image of the workpiece relative to the first axis and the second axis to verify the position of the second hole relative to the position of the second target. For example, the processor may identify the second hole with in the fourth image (e.g., an outline of the second hole) using image processing, and the processor can verify the position of the second hole relative to the position of the second target using the outline of the second target or the coordinates of the center point of the second target. For example, the position of the second hole can be verified if the outline of the second hole falls within the outline of the second target or if the second hole is centered within the second target. Accordingly, automatic optical inspection of the second target can be performed after drilling, without transferring the workpiece to a separate inspection station.

In some embodiments, the method 200 may repeat steps 211 to 218 to scan the workpiece in the second direction along the first axis for drilling the second hole and in the first direction along the first axis for optical inspection of the second hole, followed by step 209, to drill each target of the workpiece in a periodic movement process.

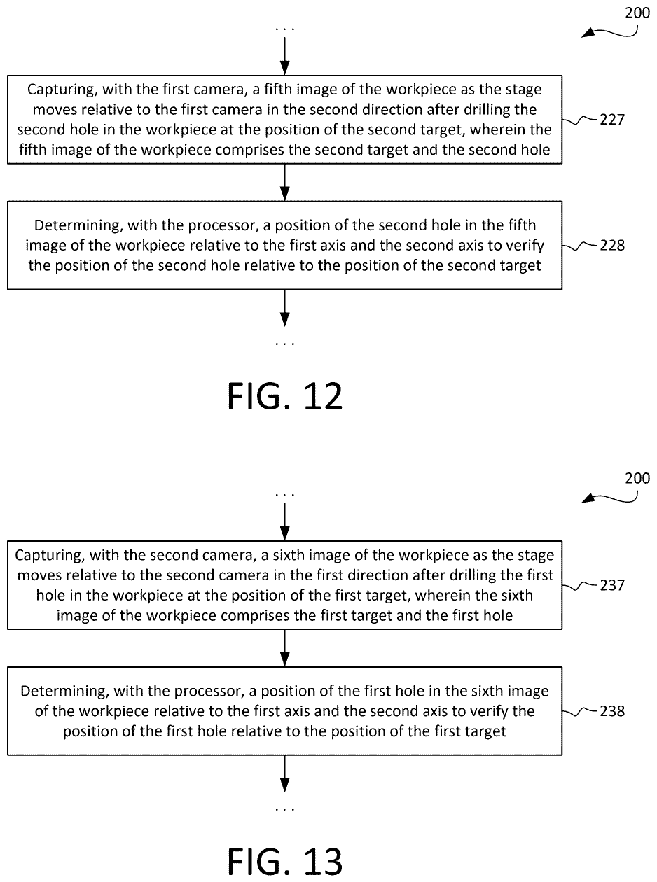

In some embodiments, the method 200 may further comprise the following steps after step 215, as shown in FIG. 12.

At step 227, the first camera captures a fifth image of the workpiece as the stage moves relative to the first camera in the second direction after drilling the second hole in the workpiece at the position of the second target. The fifth image of the workpiece comprises the second target and the second hole. In other words, rather than reversing the direction of the stage after drilling the second hole, the stage can continue to move the workpiece in the second direction along the first axis, such that the second target enters the field of view of the first camera.

At step 228, the processor determines a position of the second hole in the fifth image of the workpiece relative to the first axis and the second axis to verify the position of the second hole relative to the position of the second target. For example, the processor may identify the second hole with in the fifth image (e.g., an outline of the second hole) using image processing, and the processor can verify the position of the second hole relative to the position of the second target using the outline of the second target or the coordinates of the center point of the second target. For example, the position of the second hole can be verified if the outline of the second hole falls within the outline of the second target or if the second hole is centered within the second target. Accordingly, automatic optical inspection of the second target can be performed after drilling, without transferring the workpiece to a separate inspection station and without reversing the scanning direction of the stage.

In some embodiments, the method 200 may further comprise the following steps after step 205, as shown in FIG. 13, which describe the steps of optical inspection similar to those of steps 227 and 228 described above, but are performed in the reverse direction (i.e., the first direction) with the second camera.

At step 237, the second camera captures a sixth image of the workpiece as the stage moves relative to the second camera in the first direction after drilling the first hole in the workpiece at the position of the first target. The sixth image of the workpiece may comprise the first target and the first hole. In other words, rather than reversing the direction of the stage after drilling the first hole, the stage can continue to move the workpiece in the first direction along the first axis, such that the first target enters the field of view of the second camera.

At step 238, the processor determines a position of the first hole in the sixth image of the workpiece relative to the first axis and the second axis to verify the position of the first hole relative to the position of the first target. For example, the processor may identify the first hole with in the sixth image (e.g., an outline of the first hole) using image processing, and the processor can verify the position of the first hole relative to the position of the first target using the outline of the first target or the coordinates of the center point of the first target. For example, the position of the first hole can be verified if the outline of the first hole falls within the outline of the first target or if the first hole is centered within the first target. Accordingly, automatic optical inspection of the first target can be performed after drilling, without transferring the workpiece to a separate inspection station and without reversing the scanning direction of the stage.

In some embodiments, the method 200 may repeat steps 201 to 205 and steps 237 to 238, followed by steps 211 to 215 and steps 227 to 228, with step 209 being performed each cycle therebetween, to drill and inspect each target of the workpiece in a snaking movement process.

With the method 200, the laser beam can be directly aligned with each target of the workpiece (rather than alignment based on coordinate transformation from fiducials of the workpiece), which can improve the accuracy of drilling holes at the position of each target despite local distortion of the workpiece. In addition, the cameras can be used for automatic optical inspection of each drilled hole through the drilling process, without transferring the workpiece to a separate inspection station. Accordingly, the number of defective (i.e., misaligned) holes drilled in the workpiece can be reduced, and overall throughput can be increased. Post-drilling inspection information can also be used for correction of system drifts while processing the same workpiece, which can improve system accuracy.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a stage configured to support a workpiece and move the workpiece along a first axis, wherein the workpiece includes a first target defined on a surface of the workpiece;
a first camera disposed above the stage and configured to capture a first image of the workpiece as the stage moves relative to the first camera in a first direction, wherein the first image of the workpiece comprises the first target;
a laser source configured to emit a laser beam;
a steerable mirror configured to direct the laser beam onto the surface of the workpiece spaced apart from a field of view of the first camera in the first direction, wherein the steerable mirror is movable to direct the laser beam along a second axis that is orthogonal to the first axis; and
a processor configured to:
receive the first image of the workpiece from the first camera;
determine a position of the first target in the first image of the workpiece relative to the first axis and the second axis;
send instructions to the steerable mirror to move the laser beam to align with the position of the first target along the second axis; and
send instructions to the laser source to emit the laser beam to drill a first hole in the workpiece at the position of the first target when the laser beam is aligned with the position of the first target along the first axis by movement of the stage in the first direction.

2. The system of claim 1, wherein the first camera is further configured to capture a second image of the workpiece as the stage moves relative to the first camera in a second direction opposite to the first direction after drilling the first hole in the workpiece at the position of the first target, the second image of the workpiece comprises the first target and the first hole, and the processor is further configured to:
receive the second image of the workpiece from the first camera; and
determine a position of the first hole in the second image of the workpiece relative to the first axis and the second axis to verify the position of the first hole relative to the position of the first target.

3. The system of claim 2, wherein the processor is configured to verify the position of the first hole relative to the position of the first target when the first hole is centered within the first target.

4. The system of claim 1, wherein a plurality of targets are defined on the surface of the workpiece, the first target being one of the plurality of targets.

5. The system of claim 4, wherein the stage is further configured to move the workpiece along the second axis to index the workpiece to align a second target of the plurality of targets with a path of the laser beam as the stage moves the workpiece along the first axis.

6. The system of claim 5, further comprising:
a second camera disposed above the stage, spaced apart from the laser beam in the first direction, and configured to capture a third image of the workpiece as the stage moves relative to the first camera in a second direction opposite to the first direction, wherein the third image of the workpiece comprises the second target;
wherein the processor is further configured to:
receive the third image of the workpiece from the second camera;
determine a position of the second target in the third image of the workpiece relative to the first axis and the second axis;
send instructions to the steerable mirror to move the laser beam to align with the position of the second target along the second axis; and
send instructions to the laser source to emit the laser beam to drill a second hole in the workpiece at the position of the second target when the laser beam is aligned with the position of the second target along the first axis by movement of the stage in the second direction.

7. The system of claim 6, wherein the second camera is further configured to capture a fourth image of the workpiece as the stage moves relative to the second camera in the first direction after drilling the second hole in the workpiece at the position of the second target, the fourth image of the workpiece comprises the second target and the second hole, and the processor is further configured to:
receive the fourth image of the workpiece from the second camera; and
determine a position of the second hole in the fourth image of the workpiece relative to the first axis and the second axis to verify the position of the second hole relative to the position of the second target.

8. The system of claim 7, wherein the processor is configured to verify the position of the second hole relative to the position of the second target when the second hole is centered within the second target.

9. The system of claim 6, wherein the first camera is further configured to capture a fifth image of the workpiece as the stage moves relative to the first camera in the second direction after drilling the second hole in the workpiece at the position of the second target, the fifth image of the workpiece comprises the second target and the second hole, and the processor is further configured to:
receive the fifth image of the workpiece from the first camera; and
determine a position of the second hole in the fifth image of the workpiece relative to the first axis and the second axis to verify the position of the second hole relative to the position of the second target.

10. The system of claim 1, further comprising:
a second camera disposed above the stage, spaced apart from the laser beam in a second direction opposite to the first direction, and configured to capture a sixth image of the workpiece as the stage moves relative to the second camera in the first direction after drilling the first hole in the workpiece at the position of the first target, wherein the sixth image of the workpiece comprises the first target and the first hole;
wherein the processor is further configured to:
receive the sixth image of the workpiece from the second camera; and
determine a position of the first hole in the sixth image of the workpiece relative to the first axis and the second axis to verify the position of the first hole relative to the position of the first target.

11. The system of claim 1, wherein the first target comprises a pad, and drilling the first hole in the workpiece at the position of the first target produces a through-hole pad.

12. The system of claim 1, wherein the stage is configured to move the workpiece along the first axis at a constant velocity.

13. A method comprising:
moving, with a stage, a workpiece in a first direction along a first axis, wherein the workpiece includes a first target defined on a surface of the workpiece;
capturing, with a first camera, a first image of the workpiece as the stage moves relative to the first camera in the first direction, wherein the first image of the workpiece comprises the first target;
determining, with a processor, a position of the first target in the first image of the workpiece relative to the first axis and a second axis that is orthogonal to the first axis;
moving a steerable mirror to direct a laser beam onto the surface of the workpiece, spaced apart from the first camera in a second direction that is opposite to the first direction, to be aligned with the position of the first target along the second axis; and
emitting, with a laser source, the laser beam directed by the steerable mirror to drill a first hole in the workpiece at the position of the first target when the laser beam is aligned with the position of the first target along the first axis by movement of the stage in the first direction.

14. The method of claim 13, further comprising:
moving, with the stage, the workpiece in the second direction along the first axis after drilling the first hole in the workpiece at the position of the first target;
capturing, with the first camera, a second image of the workpiece as the stage moves relative to the first camera in the second direction, wherein the second image of the workpiece comprises the first target and the first hole; and
determining, with the processor, a position of the first hole in the second image of the workpiece relative to the first axis and the second axis to verify the position of the first hole relative to the position of the first target.

15. The method of claim 13, wherein a plurality of targets are defined on the surface of the workpiece, the first target being one of the plurality of targets, and the method further comprises:
moving, with the stage, the workpiece along the second axis to align a second target of the plurality of targets with a path of the laser beam as the stage moves along the first axis.

16. The method of claim 15, further comprising:
moving, with the stage, the workpiece in the second direction along the first axis;
capturing, with a second camera, a third image of the workpiece as the stage moves relative to the second camera in the second direction, wherein the second camera is spaced apart from the laser beam in the second direction, and the third image of the workpiece comprises the second target;
determining, with the processor, a position of the second target in the third image of the workpiece relative to the first axis and the second axis;
moving the steerable mirror to direct the laser beam onto the surface of the workpiece spaced apart from the first camera in the second direction to be aligned with the position of the second target along the second axis; and
emitting, with the laser source, the laser beam directed by the steerable mirror to drill a second hole in the workpiece at the position of the second target when the laser beam is aligned with the position of the second target along the first axis by movement of the stage in the second direction.

17. The method of claim 16, further comprising:
moving, with the stage, the workpiece in the first direction along the first axis after drilling the second hole in the workpiece at the position of the second target;
capturing, with the second camera, a fourth image of the workpiece as the stage moves relative to the second camera in the first direction, wherein the fourth image of the workpiece comprises the second target and the second hole; and
determining, with the processor, a position of the second hole in the fourth image of the workpiece relative to the first axis and the second axis to verify the position of the second hole relative to the position of the second target.

18. The method of claim 16, further comprising:
capturing, with the first camera, a fifth image of the workpiece as the stage moves relative to the first camera in the second direction after drilling the second hole in the workpiece at the position of the second target, wherein the fifth image of the workpiece comprises the second target and the second hole; and
determining, with the processor, a position of the second hole in the fifth image of the workpiece relative to the first axis and the second axis to verify the position of the second hole relative to the position of the second target.

19. The method of claim 13, further comprising:
capturing, with a second camera, a sixth image of the workpiece as the stage moves relative to the second camera in the first direction after drilling the first hole in the workpiece at the position of the first target, wherein the second camera is spaced apart from the laser beam in the second direction, and the sixth image of the workpiece comprises the first target and the first hole; and
determining, with the processor, a position of the first hole in the sixth image of the workpiece relative to the first axis and the second axis to verify the position of the first hole relative to the position of the first target.

20. The method of claim 13, wherein the first target comprises a pad, and drilling the first hole in the workpiece at the position of the first target produces a through-hole pad.
